(19) United States
(12) Patent Application Publication
(10) Pub. No.: US 2008/0073710 A1
(43) Pub. Date: Mar. 27, 2008

(54) Semiconductor device with a vertical MOSFET and method for manufacturing the same

(75) Inventor: Hideo Yamamoto, Kawasaki (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KAWASAKI (JP)

(21) Appl. No.: 11/902,243

(22) Filed: Sep. 20, 2007

(30) Foreign Application Priority Data
Sep. 26, 2006 (JP) 2006-260019

(51) Int. Cl. H01L 29/78; H01L 21/336

(52) U.S. Cl. 257/334; 438/270; 257/E29.262; 257/E21.41

(57) ABSTRACT

The size of a gate contact region is decreased by connecting a gate connection electrode embedded in a trench and a gate wiring formed over the gate connection electrode, without forming another conductive film different from the gate connection electrode or the gate wiring. The semiconductor body includes an active cell region and a gate contact region. The active cell region includes a vertical MOSFET with a gate electrode disposed in a first trench. The gate contact region includes the gate connection electrode disposed in a second trench and formed of a same conductive material with the gate electrode. The gate connection electrode includes an embedded part formed in the second trench and an extended part extended therefrom and formed outside the second trench. An interlayer insulation film formed on the gate connection electrode and having a via hole exposing at least a portion of the embedded part of the gate connection electrode.

### CROSS-REFERENCE TO RELATED APPLICATIONS

This application is based upon, claims the benefit of priority of, and incorporates by reference the contents of Japanese Patent Application No. 2006-260019 filed on Sep. 26, 2006.

### BACKGROUND

1. Field of the Invention

The present invention relates to a semiconductor device, and a manufacturing method thereof. More particularly, the invention relates to a semiconductor device including a vertical metal-oxide semiconductor field effect transistor (MOSFET), and a manufacturing method thereof.

2. Description of Related Art

Generally, vertical-type MOSFETs (metal-oxide semiconductor field effect transistor) are used for power devices such as power MOSFETs. Some power MOSFETs have a structure in which a gate electrode is formed to the inside of a trench. FIG. 7 is a cross sectional view showing the structure of a semiconductor device 10 described in Japanese Unexamined Patent Application Publication No. 2002-368221 and U.S. Pat. No. 6,639,275 B2. The semiconductor device 10 has an active cell region A and a gate contact region B above a first conductivity type semiconductor body 11. A first conductivity type epitaxial layer as a drift region 12 is formed on the semiconductor body 11. The semiconductor body 11 and the drift region 12 function as a drain of the power MOSFET. Second conductivity type base regions 17 and first conductivity type source regions 18 are formed above the epitaxial layer. A trench 13 is formed to a thickness of passing through the source regions 18 and the base regions 17 and reaching the drift region 12. A portion of the trench 13 in the active cell region A corresponds to a first trench, and a portion of the trench 13 in the gate contact region B corresponds to a second trench. A gate insulating film 14 is formed to the inner surface of the trench 13, and the gate electrode 15 and a gate connection electrode 25 are formed in the active cell region A and gate contact region B respectively. The gate electrode 15 and the gate connection electrode 25 are formed by stacking a polysilicon layer above the entire surface of the semiconductor body and then etching back the same. The polysilicon layer deposited to the region other than the trench 13 is removed by etching, and the gate electrode 15 and the gate connection electrode 25 are formed only in the inside of the trench 13.

An interlayer insulation film 20 is formed above them. Then, via holes 22 reaching the base regions 17 and the source regions 18 are formed in the active cell region A, and via holes 23 reaching the gate connection electrode 25 are formed in the gate contact region B. Conductive plugs 132 and 133 are formed so as to bury the via holes 22 and the via holes 23 respectively. Then, a conductive film is stacked on the interlayer insulation film 20 and patterned to form a source electrode 121 in the active cell region A and a gate wiring 122 in the gate conduct region B. Since the semiconductor device 10 does not adopt a conventional structure of forming a gate connection electrode by extending the polysilicon layer as the constituent material for the gate connection electrode 25 to the outside of the trench 13 and connecting the same with the gate wiring 122, but the gate connection electrode 25 and the gate wiring 122 are connected by a conductive plug 133 just above the gate connection electrode 25, the size of the gate contact region B can be made smaller than that of the conventional structure.

However, for lowering the on resistance per unit chip area, it has been demanded to form a more refined gate electrode 15 in a more defined trench 13 thereby increasing the effective number of channels or the channel width. Even if the refinement of the trench 13 and the refinement of the gate electrode 15 are possible, since the contact between the gate connection electrode 25 and the gate wiring 122 is formed by using a photolithographic technique, an alignment margin has to be ensured. That is, as the width of the trench 13 viewed on the side of the surface of the gate connection electrode 25 is narrowed, the size of the via holes 23 formed in the interlayer insulation film 20 covering the surface of the gate connection electrode 25 has to be made smaller than the width of the trench 13. Since the alignment margin has also to be decreased for forming such a small via hole 23, alignment at a higher accuracy is necessary, and this is difficult in view of the process and lowers the production yield as well.

Further, since the size of the via hole has to be decreased, conductive plugs 133 made of a conductive material such as tungsten easy for embedding are necessary for the connection with the gate connection electrode 25.

Furthermore, even when the alignment can be attained with difficulty, the conductive material can not be embedded effectively if the via holes 133 are narrow to form voids or the like possibly resulting in increase in the resistance value.

By the way, Japanese Unexamined Patent Application Publication No. HEI 7-202015 and U.S. Pat. No. 5,484,739 disclose techniques, for ensuring the alignment margin upon forming via holes in the interlayer insulation film for connecting an electrode to the n-type semiconductor region, by forming a connection pad layer of a width larger than that of the n-type semiconductor region over the n-type semiconductor region and forming the via holes to the connection pad layer. However, since this method requires another conductive film as a connection pad layer, this result in a problem of increasing the production step and increasing the cost and it can not be adopted.

In the technique of forming the contact between the gate connection electrode and the gate wiring as described above, reduction of the alignment margin causes lowering of the production yield. Further, along with refinement of the via hole size, a conductive material such as tungsten that can be formed by CVD (Chemical Vapor Deposition) and embedding into the fine via holes is necessary to result in the increase in the cost. Furthermore, means for forming another conductive film over the trench for improving the operation efficiency of etching increases the production steps which causes increase in the cost.

### SUMMARY

The present invention seeks to solve or to improve one or more of the above problems at least in part by making contact between the gate connection electrode formed in the trench and the gate wiring just above the gate connection electrode without increasing the photolithographic step.

In one embodiment of the present invention, a gate electrode and a gate connection electrode are formed in a first trench of an active cell region and a second trench of a gate contact region, respectively. The gate connection electrode is formed of a conductive material that is the same material of the gate electrode. The gate connection electrode includes an embedded part that is formed in the second trench and an extended part that is extended from the embedded part and is formed outside of the second trench. An interlayer insulation film is formed on the gate connection electrode. A via hole is formed in the interlayer insulation film so as to overlap with the embedded part of the gate connection electrode. And a gate wiring is connected to the gate connection electrode through the via hole.

According to the one embodiment of the present invention, by embedding the gate connection electrode embedded in the second trench and connecting the gate wiring to the extended part of the gate connection electrode extended from an opening of the second trench, the size of the gate contact region can be decreased without forming another conductive film different from the gate connection electrode or the gate wiring. That is, a degree of freedom can be ensured for the arrangement of via holes for making the contact with the conductive film by the gate connection electrode embedded in the second trench and extended from the opening of the second trench, in the gate contact region and the alignment margin can be ensured. Further, since the width of the via holes is enlarged, it is not necessary to form another conductive film different from the gate connection electrode and the gate wiring (for example, conductive plugs 133 shown in FIG. 7 or a connection pad in Japanese Unexamined Patent Application Publication No. HEI 7-202015 and U.S. Pat. No. 5,484,739) thereby dissolving the problem in the increase of the cost.

According to the invention, connection of the gate wiring to the refined gate connection electrode can be attained easily.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a fragmentary plan view of a semiconductor device 100 of the first embodiment of the present invention;

FIG. 2 is a cross sectional view along line II-II in FIG. 1;

FIGS. 3A-3D are cross sectional views showing a process for manufacturing the semiconductor device 100;

FIG. 4 is a fragmentary plan view of a semiconductor device 200 of the second embodiment of the present invention;

FIG. 5 is a cross sectional view along line V-V in FIG. 4;

FIGS. 6A-6D are cross sectional views showing a process for manufacturing the semiconductor device 200;

FIG. 7 is a cross sectional view showing a semiconductor device 10 in the prior art;

FIGS. 8A and 8B are a plan view and a cross sectional view, respectively, showing a modified semiconductor device of the second embodiment of the present invention; and

FIGS. 9A and 9B are a plan view and a cross sectional view, respectively, showing another modified semiconductor device of the second embodiment of the present invention.

### DETAILED DESCRIPTION OF THE PREFERRED EMBODIMENT

The invention will be now described herein with reference to illustrative embodiments. Those skilled in the art will recognize that many alternative embodiments can be accomplished using the teachings of present invention and that the invention is not limited to the embodiments illustrated for explanatory purposes.

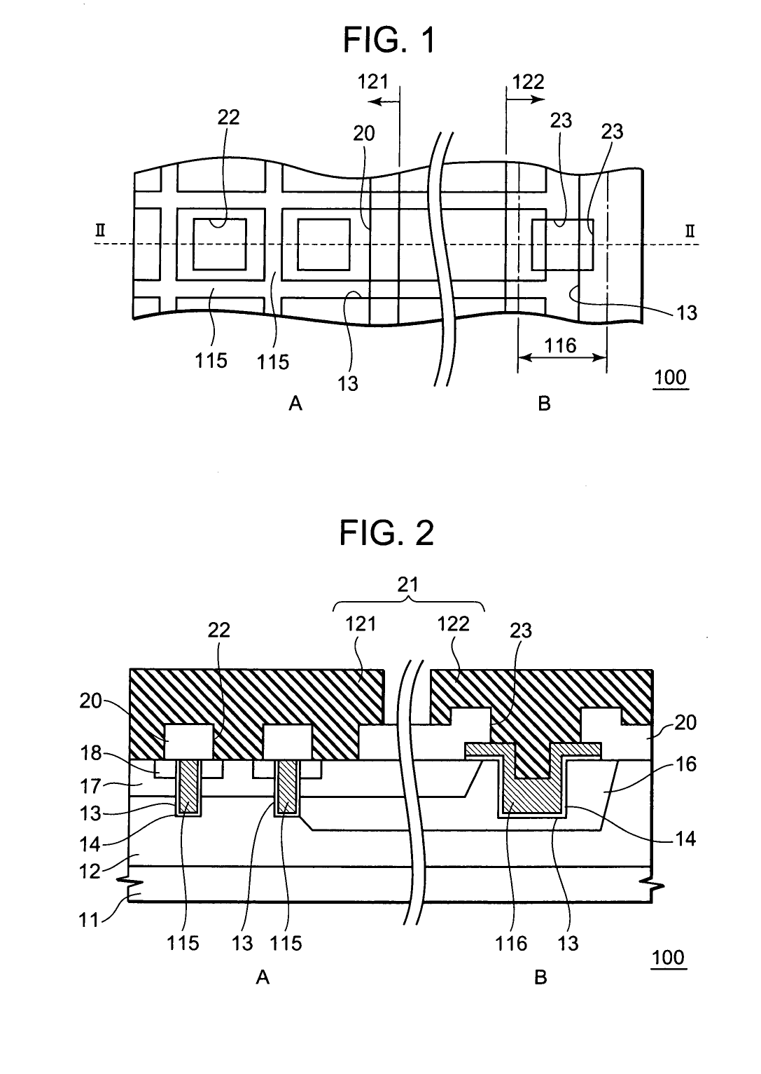

Preferred embodiments of the present invention are to be described with reference to the drawings. FIG. 1 is a fragmentary plan view of a semiconductor device 100 according to the first embodiment of the present invention and FIG. 2 is a cross sectional view corresponding to line II-II in FIG. 1.

A semiconductor body 11 shown in FIG. 1 is an n⁺-type semiconductor body having an active cell region A and a gate contact region B and formed, for example, of silicon. The active cell region A means a region forming an active cell and the gate contact region B means a region in which a gate connection electrode 116 extended from a gate electrode 115 is in contact with a gate wiring 122 shown in FIG. 2. A drift region 12 is formed over the entire surface on the semiconductor body 11 by epitaxial growing. The drift region 12 is, for example, an n⁻-type semiconductor layer and operates together with the semiconductor body 11 as the drain of a vertical-type MOSFET. A not illustrated drain electrode is formed to the rear surface of the semiconductor body 11. A plurality of base regions 17 are formed on the drift region 12. The base regions 17 are, for example, a boron-containing p-type semiconductor region, which is a region where a channel is formed near the gate electrode 15 upon operation of the vertical-type MOSFET. Further, a source region 18 adjacent with the trench 13 is formed on each of the base region 17 of the active cell region A. The source regions 18 are, for example, an n⁺-type semiconductor region containing arsenic that operates as a source for the MOSFET. In the following description, the gate electrode 115 in the active cell region A corresponds to the gate electrode 15 of the conventional active cell region A, and the gate connection electrode 116 in the gate contact region B corresponds to the gate connection electrode 25 of the conventional gate contact region B. FIG. 1 shows a single trench example in which a trench 13 is formed in a lattice shape, and the gate electrode 115 and the gate connection electrode 116 are connected in a lattice shape to form a single-piece. This is not restrictive but the trenches 13 may be shaped into plural stripes and the combination of the gate electrodes 115 and the gate connection electrodes 116 are in plural stripes.

The structure of the gate electrode 115 in the active cell region A is to be described. Above the semiconductor body 11, a trench 13 is formed so as to be deeper than the base regions 17. A gate insulating film 14 is formed to the inner surface of the trench 13 so as to cover the inner surface of the trench 13. The inside of the trench 13 is substantially filled up to the opening, for example, with a first polysilicon layer by way of the gate insulative film 14 to form the gate electrode 115.

Then, the structure for the gate connection electrode 116 in the gate contact region B is to be described. Above the semiconductor body 11, a trench 13 is formed reaching a position deeper than the base region 17 and to a position not exceeding a well region 16. The well region 16 is formed of a p-type semiconductor region like the base region 17. While the invention can be practiced without disposing the well region 16, the drain-gate withstanding voltage can be improved by forming the well region 16 which is a p-type region as far as the position below the bottom of the trench 13. The gate insulating film 14 is extended to the wall surface and the bottom of the trench 13 and to the edge of the opening of the trench 13, and for example, a first polysilicon layer is extended above the gate insulating film 14 to the wall surface and the bottom of the trench 13, as well as to the edge of the opening of the trench 13, to form the gate connection electrode 116. Apart of the gate connection electrode 116 in the trench 13 is referred to as an embedded part, a part of the gate connection electrode 116 extended from the embedded part and formed outside of the second trench is referred to as an extended part.

Further, an interlayer insulation film 20 is formed above the entire surface of the semiconductor body 11 on the gate electrode 115 in the active cell region A and the gate connection electrode 116 in the gate contact region B. The interlayer insulation film 20 is formed, for example, of BPSG (Boron-doped Phospho-Silicate Glass).

As shown in FIG. 2, plural via holes are formed in the interlayer insulation film 20. The via holes 22 in the active cell region A are formed above the base regions 17 and the source regions 18. The via holes 22 are formed passing through the interlayer insulation film 20. The via holes 22 are formed such that the bottom thereof reaches the base regions 17 and the source regions 18.

The via holes 23 in the gate contact region B are formed above the gate connection electrode 116. The via holes 23 are formed passing through a portion of the interlayer insulation film 20 above the gate connection electrode 116. Since the extended part of the gate connection electrode 116 is formed being extended from the opening of the trench 13, the width of the via holes 23 can be set larger than the width of the opening of the trench 13. The via holes 23 are formed so as to overlap with the embedded part of the gate connection electrode 116. While an example in which the interlayer insulation film 20 does not remain in a concave portion of the embedded part of the gate connection electrode 116 is shown herein, there is no problem in a case where the interlayer insulation film 20 remains at the bottom of the concave portion of the embedded part of the gate connection electrode 116.

Further, a conductive film 21 is formed on the interlayer insulation film 20 and in the via holes 22 and 23. The conductive film 21 is formed by patterning a conductive material such as aluminum or copper into a predetermined shape. The conductive film 21 forms a source electrode 121 and a gate wiring 122.

The source electrode 121 is electrically connected by way of the via holes 22 in the active cell region A with the base regions 17 and the source regions 18. The gate wiring 122 is electrically connected by way of the via holes 23 in the gate contact region B to the gate connection electrode 116.

In the conventional semiconductor device 10, since conductive plugs 133 were intended to be formed so as not to be out of alignment from the gate connection electrode 25, the alignment margin is restricted and improvement for the yield was difficult. Further, due to the refinement of the via holes connecting the conductive film and the gate electrode, conductive plugs formed, for example, of tungsten or titanium were necessary and increase in the cost was inevitable by the increase in the number of steps and the increase in the number of parts.

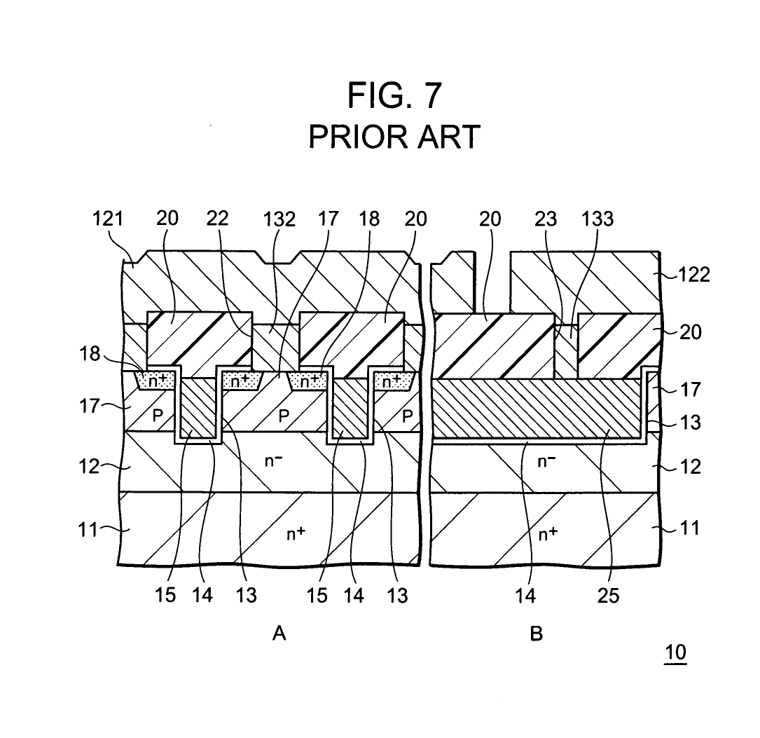

However, according to the semiconductor device 100 of the first embodiment, the alignment margin can be ensured sufficiently by forming the gate connection electrode 116 larger than the width of the trench 13 in the gate contact region B. That is, it is no more necessary to ensure the alignment margin of the via holes 23 to the trench 13. Since the via holes 23 are formed reliably in the gate connection electrode 116 insulated by the gate insulating film 14 from the base region 17 or the well region 16, there is no possibility of short-circuit between the via holes 23 and the doped region. Accordingly, since the via holes 23 can be enlarged, the yield can be improved. In addition, since the via holes 23 are formed so as to overlap with the trench 13 in which the gate connection electrode 116, the size of the gate contact region B can be reduced about to the same extent as that of the semiconductor device 10 in FIG. 7. The extended part of the gate connection electrode 116 is considerably smaller compared with the size of the gate wiring 122 and the gate contact region B is not enlarged by the extended part. Further, since the gate connection electrode 116 is formed of the conductive material identical with that of the gate electrode 115 in the active cell region A and formed of aluminum or copper not by CVD but by sputtering and the conductive layer 21 difficult to be embedded into fine via holes can be formed in the via holes 23, conductive plugs formed of tungsten, titanium or the like and addition of another conductive film for extending the alignment margin are not necessary.

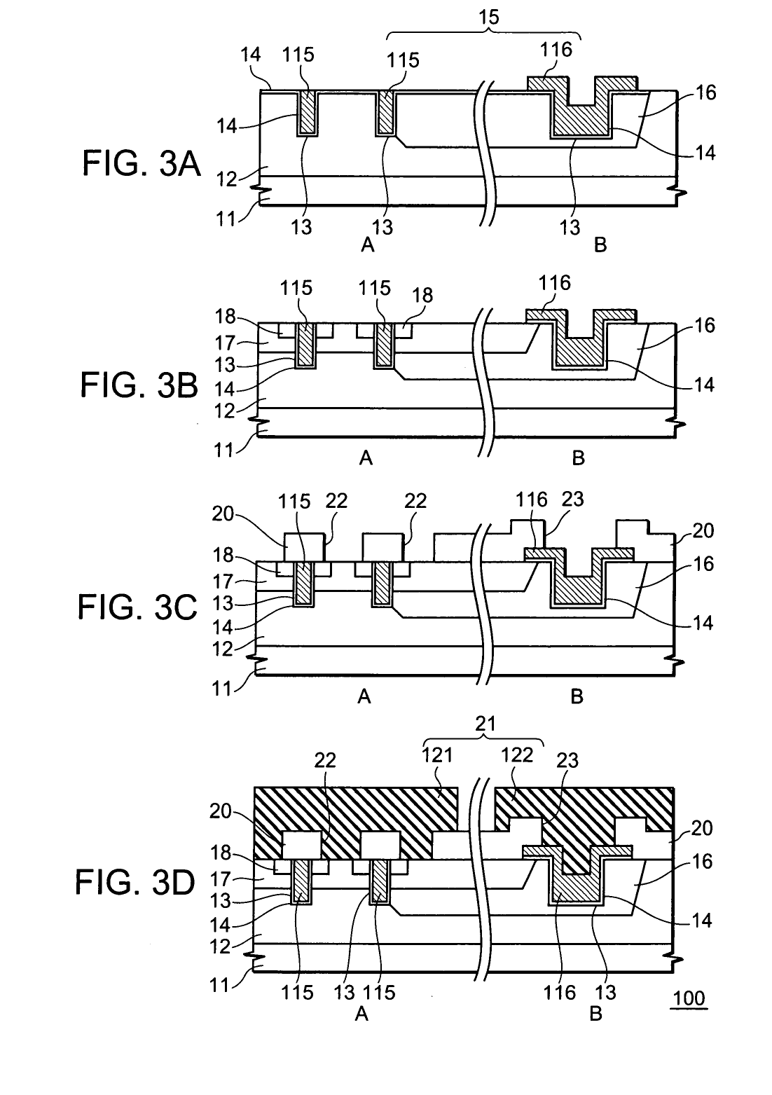

Then, a process for manufacturing the semiconductor device 100 is to be described with reference to FIG. 3A to FIG. 3D. As shown in FIG. 3A, a drift region 12 of an n⁻-type semiconductor is epitaxially grown over the entire surface of an n⁺-type semiconductor body 11. Then, after ion implanting p-type impurities such as boron (B) in the drift region 12 of a gate contact region B, a heating treatment is applied to form a well region 16 as a p-type diffusion layer. Then, by conducting RIE (Reactive Ion Etching) by using a not illustrated mask, the drift region 12 is removed selectively. By the etching, a trench 13 is formed to the drift region 12 in the active cell region A and to the well region 16 in the gate contact region B.

Subsequently, by applying thermal oxidation, for example, in an H₂—O₂ atmosphere, a gate insulating film 14 is formed to the surface of the drift region layer 12 and the surface of the inner wall of the trench 13.

Then, a conductive layer is deposited above the semiconductor substrate 11 entirely, for example, by a low-pressure CVD method. In this embodiment, a polysilicon layer is deposited as the conductive layer. The thickness of the polysilicon layer deposited in this step is set such that the silicon layer can bury the entire inside of the trench 13 in the active cell region A. The trench 13 in the gate contact region B is not necessary fully buried. Then, a mask (not illustrated) for leaving the gate connection electrode 116 in the gate contact region B is formed, and the polysilicon layer is patterned by plasma RIE. In the active cell region A, etching back is applied for the entire surface such that the polysilicon layer is left only in the inside of the trench 13 to form a gate electrode 115 embedded in the trench 13. Further, in the gate contact region B, a mask (not illustrated) for covering a range larger than the opening of the trench 13 is formed on the polysilicon layer and etched simultaneously to form a extended part of the gate connection electrode 116. The extended part of the gate connection electrode 116 can be designed optionally while taking the alignment margin of the via holes 23 into consideration.

Then, after ion implanting p-type impurities such as boron (B) above the semiconductor body 11, a heating treatment is applied. By the step, a p-type base region 17 of a conductivity type opposite to that of the drift region 12 is formed in the drift region 12.

Successively, n-type impurities such as arsenic (As) are ion implanted from above the base region 17 adjacent with the gate electrode 115 in the active cell region A and, further, a heating treatment is applied. Thus, as shown in FIG. 3B, an n⁺-type source region 18 is formed to the surface of the base region 17 in adjacent with the gate electrode 115 in the active cell region A.

Then, as shown in FIG. 3C, a BPSG layer or the like is deposited above the semiconductor body 11 over the entire surface by an atmospheric-pressure CVD method to form an interlayer insulation film 20. Successively, the interlayer insulation film 20 is removed selectively by RIE using a not illustrating mask. By the etching, the interlayer insulation film 20 at a portion corresponding to the via holes 22 in the active cell region A and the via holes 23 in the gate contact region B is removed. By the removal, a co-surface of the base regions 17 and the source regions 18 is exposed to the bottom of the via holes 22 in the active cell region A, and the surface of the gate connection electrode 116 is exposed to the bottom of the via holes 23 in the gate contact region B.

Then, as shown in FIG. 3D, a conductive film 21 is formed above the semiconductor body 11 entirely, for example, by sputtering of aluminum. The conductive film 21 is patterned by etching using a not illustrated mask to form a source electrode 121 in the active cell region A and form a gate wiring 122 in the gate contact region B. The semiconductor device 100 is manufactured by the steps described above.

In the process for manufacturing the semiconductor device of FIG. 7, when compared with the step in FIG. 3C, the via holes 23 in the gate contact region B have to be formed narrower than the width of the opening of the trench 13. Therefore, a high alignment accuracy was required upon forming the mask for forming the via holes 23 and it was difficult to improve the yield. Further, refinement of the via holes 23 required the conductive plugs 133 formed, for example, of tungsten or titanium which can be embedded into a fine via holes and this inevitably increased the cost due to the increase for the number of steps and increase for the number of parts. Furthermore, means for additionally forming another conductive film in order to enlarge the alignment margin increased the manufacturing steps leading to increase of the cost.

However, according to the process for manufacturing the semiconductor device 100 described above, since it is no more necessary to ensure the alignment margin of the via holes 23 to the gate connection electrode 116 relative to the trench 13 in the step of FIG. 3C, the width of the via holes 23 can be enlarged to the same extent or larger than the width for the opening of the trench 13 to improve the yield. Further, since the width of the via holes 23 in the gate contact region B can be enlarged, the conductive plugs are no more necessary. Further, means for additionally forming another conductive film on the trench is no more necessary. Accordingly, it is possible to decrease the number of the manufacturing steps and decrease the cost.

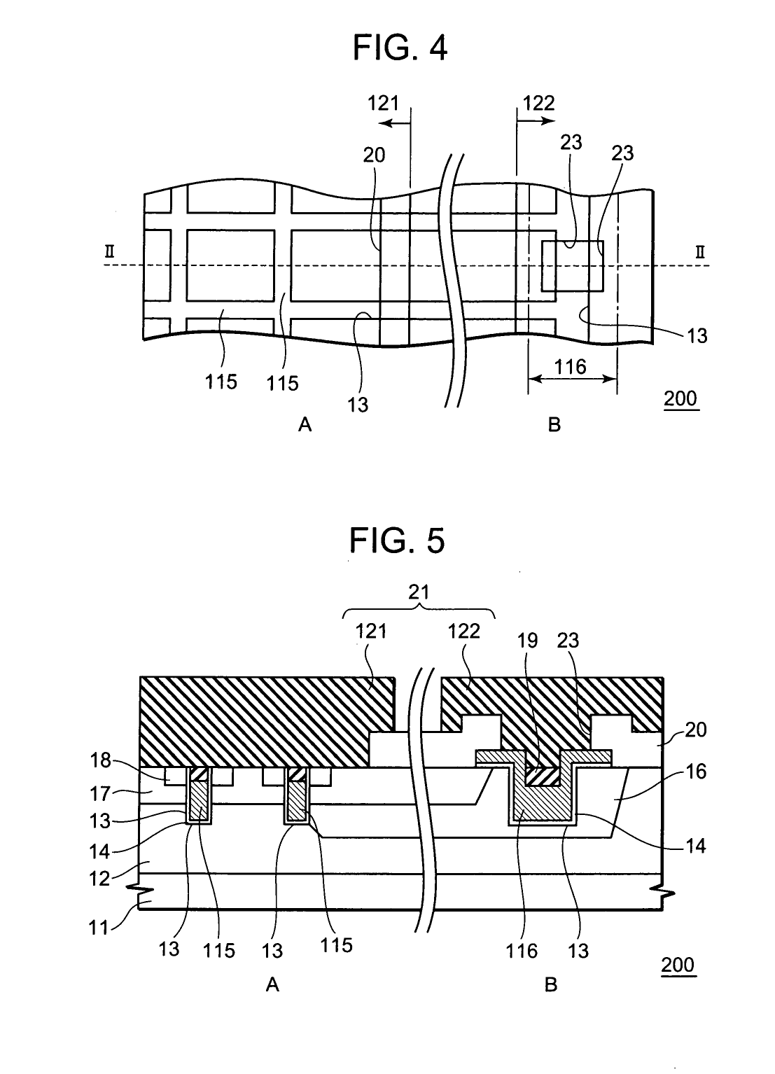

Then, a semiconductor device 200 according to a second embodiment of the present invention is to be described with reference to the drawings. FIG. 4 is a fragmentary plan view of the semiconductor device 200 and FIG. 5 is a cross sectional view corresponding to line V-V in FIG. 4. Since the entire constitution of the semiconductor device 200 is similar to the constitution shown in FIG. 2, therefore an explanation of the same part is to be omitted. In the semiconductor device 200, an embedded insulating film 19 is formed in the trench 13 of the gate contact region B and it is a characteristic feature that the film 19 is formed so as to cover a portion above the gate electrode 115 in the active cell region A and formed so as to cover a portion of the embedded part of the gate connection electrode 116 in the gate contact region B.

According to the semiconductor device 200, the gate electrode 115 and the source electrode 121 are electrically insulated by the embedded insulating film 19 and since it is not necessary to form the interlayer insulation film 20 as in FIG. 2 above the base regions 17 and the source regions 18, formation of the via holes 22 in the active cell region A is no more necessary. Accordingly, in the semiconductor device 100 in FIG. 2, while the edge of the source electrode 121 (edge for the via holes 22) and the edge of the gate electrode 115 are spaced laterally for insulating the source electrode 121 and the gate electrode 115, since such lateral isolation space is no more necessary in the semiconductor device 200 in FIG. 5, the cell size of the MOSFET can be decreased.

While the embedded insulating film 19 is formed also to the embedded part of the gate connection electrode 116 in the gate contact region B, by forming the via holes 23 so as to partially expose the gate connection electrode 116, since the gate wiring 122 and the gate connection electrode 116 are in contact with each other in an L-shaped configuration above the embedded insulating film 19, there is no problem even when the embedded insulating film 19 is left.

Since the embedded insulating film 19 is embedded in the inside of the trench of the trench 13 in the active cell region A and the embedded insulating film 19 is buried to the upper side also to the trench 13 in the gate contact region B, the step near the via holes 23 is decreased to less than that in the semiconductor device 100 and the conductive film 21 can be formed more planar.

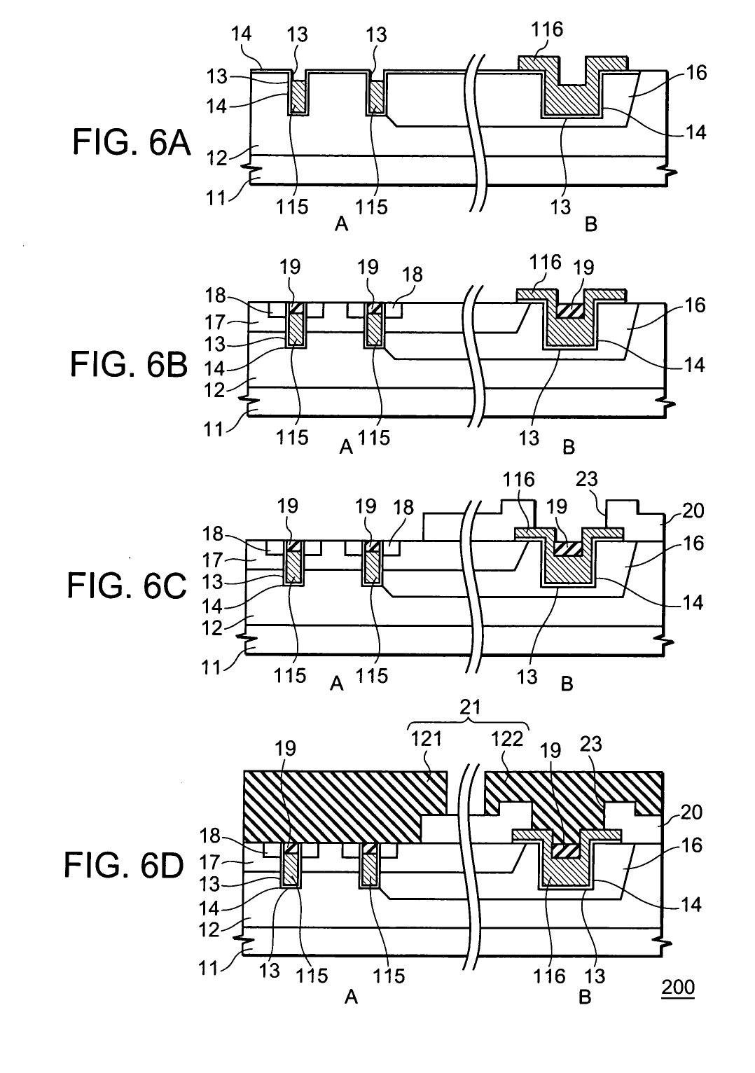

Then, a process for manufacturing the semiconductor device 200 is to be described with reference to FIG. 6A to FIG. 6D. For the portions identical with those in the semiconductor device 100, descriptions are to be omitted. The process for manufacturing the semiconductor device 200 has a feature of including a step of forming the embedded insulating film 19 to the trench 13 in the active cell region A and to the trench 13 in the gate contact region B.

A polysilicon layer as a conductive layer is deposited above the semiconductor substrate 11 entirely by a low-pressure CVD method. Then, a mask (not illustrated) for leaving the gate connection electrode 116 in the gate contact region B is formed and the polysilicon layer is patterned by plasma RIE. In the active cell region A, the polysilicon layer is etched back for the entire surface as far as a position lower than a lip of the opening of the trench 13, and an upper portion of the trench 13 is left above the gate electrode 115. In the gate contact region B, since a mask (not illustrate) for covering a wider range than the opening of the trench 13 is formed above the polysilicon layer and etched simultaneously, the gate connection electrode 116 is formed in the same manner as in the semiconductor device 100 (FIG. 6A).

Then, as shown in FIG. 6B, by forming for example, NSG (Non-doped Silicate Glass) over the entire surface by an atmospheric pressure CVD method and etching back the same, an embedded insulating film 19 is buried to the inside of the trench 13 in the active cell region A so as to cover the upper surface of the gate electrode 115, and an embedded insulating film 19 is formed on the gate connection electrode 116 in the gate contact region B so as to cover a portion thereof. By the embedded insulating film 19, the gate electrode 115 and the source electrode 121 are electrically insulated in the active cell region A.

The embedded insulating film 19 above the gate connection electrode 116 in the gate contact region B may be removed. While the unevenness like in the semiconductor device 100 is formed to the gate wiring 122, the contact resistance between the gate connection electrode 116 and the gate wiring 122 is lowered in the same manner by removing the embedded insulating film 19 as in the semiconductor device 100.

Then, as shown in FIG. 6C, a BPSG layer or the like is deposited over the entire surface by an atmospheric pressure CVD method to form an interlayer insulation film 20. Successively, by applying RIE using a not illustrated mask, the interlayer insulation film 20 is removed selectively. In the active cell region A, since via holes are not necessary to be formed, the interlayer insulation film 20 is removed entirely and via holes 23 are formed to the interlayer insulation film 20 in the gate contact region B. In the active cell region A, a co-surface of the embedded insulating film 19, the base region 17, and the source region 18 is exposed, and surfaces of the embedded insulating film 19 and a portion of the gate connection electrode 116 are exposed to the bottom of the via holes 23 in the gate contact region B.

Then, as shown in FIG. 6D, a conductive film 21, for example, of aluminum or copper is sputtered and etched by using a not illustrated mask to form a source electrode 121 and a gate wiring 122. With a steps described above, the semiconductor 200 is manufactured.

According to the process for manufacturing the semiconductor device 200 of the second embodiment, since the lateral distance between the edge of the source electrode 121 and the edge of the gate electrode 115 can be decreased by burying the embedded insulating film 19 in the trench 13 so as to cover the gate electrode 115 in active the cell region A, the cell size of the MOSFET can be made smaller than that of the semiconductor device 100.

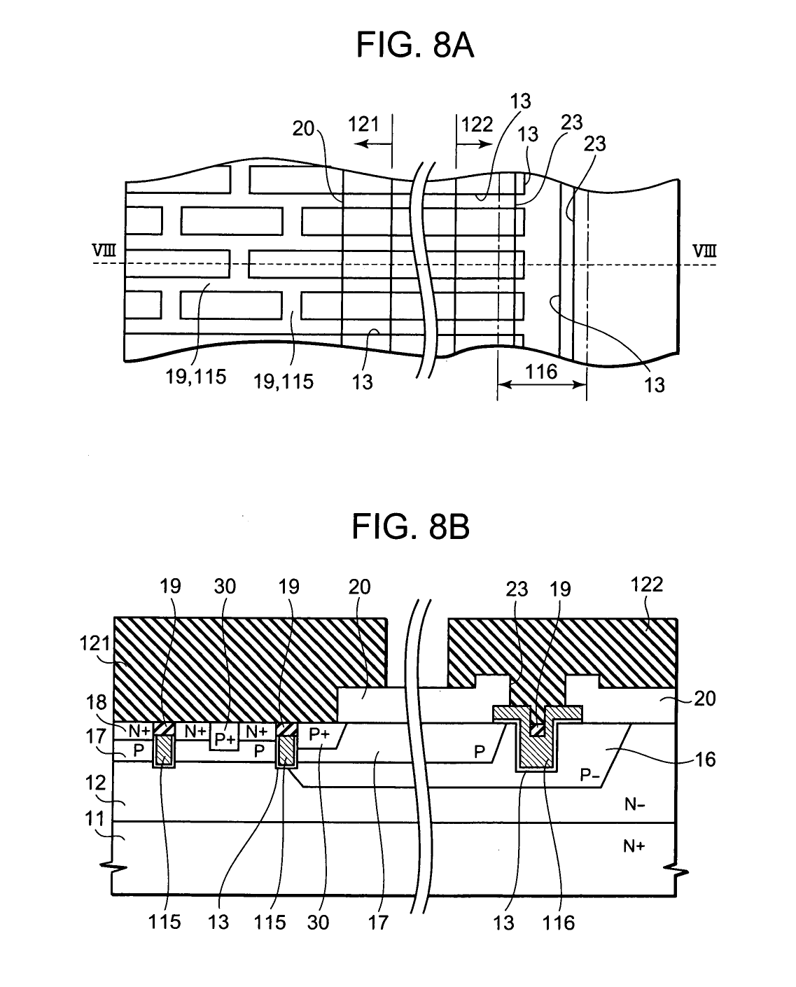

FIG. 8A is a fragmentary plan view of a modified example similar to the semiconductor device 200. FIG. 8B is a cross sectional view corresponding to line VIII-VIII in FIG. 8A. The trench 13 in the active cell region is formed in a hound's tooth check shape in a plan view. The base regions 17 are electrically connected to the source electrode 121 via a P⁺-type base contact region 30. An elongated via hole 23 is formed along a vertical direction to line VIII-VIII, the gate connection electrode is in contact with the gate wiring 122 so that a resistance between the gate wiring 122 and the gate connection electrode 116 may be reduced.

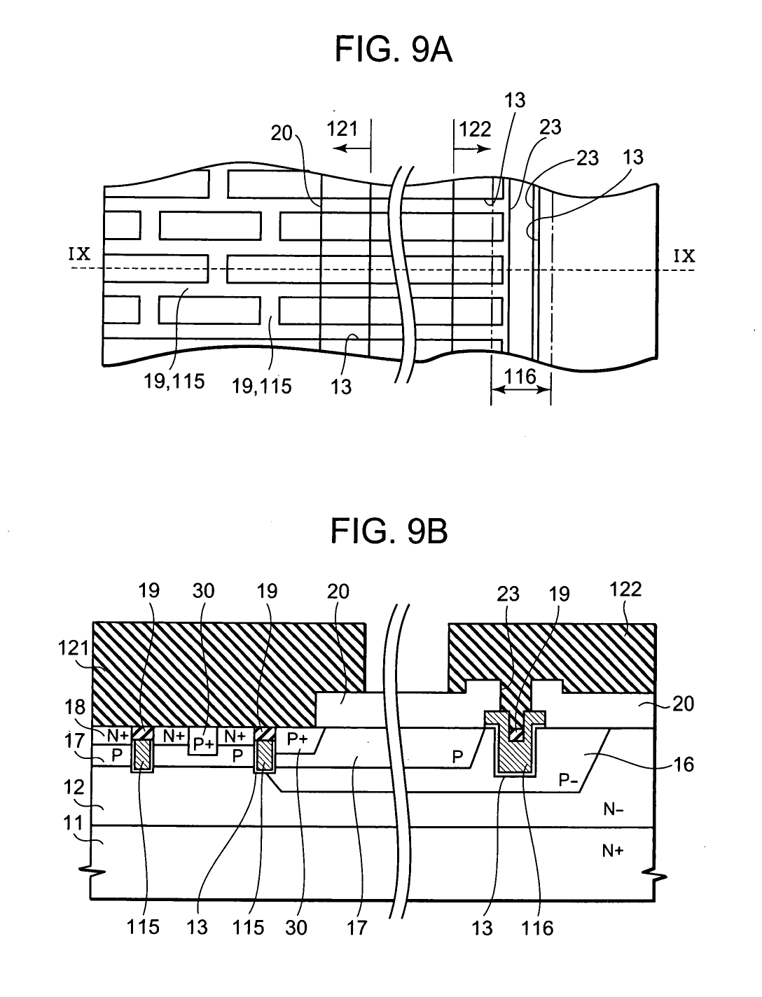

FIG. 9A is a fragmentary plan view of another modified example similar to the semiconductor device shown in FIG. 8A. FIG. 9B is a cross sectional view corresponding to line IX-IX in FIG. 9A. The difference is that the via hole 23 is slight narrower than the trench 13. When considering an unexpected reduction of the film thickness of the extended part of the gate connection electrode 116 in FIG. 8B due to an over etching of the interlayer insulation film 20, it is preferred to form the via hole 23 in such a way that an edge of the via hole 23 overlaps with a thicker portion of the embedded part that abuts on a sidewall of the trench 13. Even if an unexpected over etching of the interlayer insulation film 20 occurs, a remaining film thickness of the gate connection electrode 116 would be sufficient.

Further, while it has been described that n-type is the first conductivity type and the p-type is the second conductivity type, they may be reversed.

Although the invention has been described above in connection with several preferred embodiments thereof, it will be appreciated by those skilled in the art that those embodiments are provided solely for illustrating the invention, and should not be relied upon to construe the appended claims in a limiting sense.

What is claimed is:

1. A semiconductor device, comprising:
a semiconductor body including an active cell region and a gate contact region;
a base region formed in said semiconductor body in said active cell region;
a first trench formed in said base region in said active cell region;
a gate electrode formed in said first trench;
a source region formed in said base region in said active cell region;
a source wiring connected to said source region and said base region in said active region;
a second trench formed in said semiconductor body in said gate contact region;
a gate connection electrode formed in said second trench, said gate connection electrode including an embedded part that is formed in said second trench and an extended part that is extended from said embedded part and is formed outside of said second trench,
an interlayer insulation film formed on said gate connection electrode and having a via hole over lapping with said embedded part of said gate connection electrode; and
a gate wiring connected to said gate connection electrode through said via hole.

2. The semiconductor device according to claim 1, wherein said via hole further exposes a portion of said extended part of said gate connection electrode.

3. The semiconductor device according to claim 1, further comprising an embedded insulating film,
wherein said gate electrode is partially filled in said first trench in said active cell region, and
wherein a remaining portion of said first trench in said active cell region is filled with said embedded insulating film is formed on said gate electrode.

4. The semiconductor device according to claim 3, wherein said embedded insulating film is further formed on said embedded part of said gate connection electrode.

5. The semiconductor device according to claim 1, wherein said source electrode and said gate wiring are formed of a same conductive material.

6. A process for manufacturing a semiconductor device, comprising:
forming a first trench in an active cell region in a semiconductor body and a second trench in a gate contact region in said semiconductor body, respectively;
forming a gate insulating film and a conductive material in each of said first trench and said second trench;
patterning said conductive material and forming a gate electrode in said first trench and a gate connection electrode in said second trench, said gate connection electrode including an embedded part that is formed in said second trench and an extended part that is extended from said embedded part and is formed outside of said second trench;
forming an interlayer insulation film on said gate connection electrode;
forming a via hole in said interlayer insulation film so as to overlap with said embedded part of said gate connection electrode; and
forming a gate wiring connected to said gate connection electrode through said via hole.

7. The process for manufacturing a semiconductor device according to claim 6, wherein said via hole further exposes a portion of said extended part of said gate connection electrode.

8. The process for manufacturing a semiconductor device according to claim 6, further comprising:
forming an embedded insulating film on said gate electrode in said first trench;
forming a base region in said active element region in said semiconductor body;
forming a source region in said base region; and
forming a source electrode connected to said source region and said base region in said active element region,
wherein said gate electrode is partially filled in said first trench, said embedded insulating film is formed on said gate electrode in the remaining portion of said first trench, and
wherein said source electrode is formed on a substantially coplanar surface formed by the upper surface of each of said base region, said source region, and said embedded insulating film.

9. The process for manufacturing a semiconductor device according to claim 8, wherein said forming said embedded insulating film is further forming another embedded film on said embedded part of said gate connection electrode, and said gate wiring contacts to both of said gate connection electrode and said another embedded insulating film.

10. The semiconductor device according to claim 8, wherein the source electrode and the gate wiring are formed simultaneously.
